(19) United States
(12) Patent Application Publication
(10) Pub. No.: US 2015/0064496 A1
(43) Pub. Date: Mar. 5, 2015

(54) SINGLE CRYSTAL COPPER, MANUFACTURING METHOD THEREOF AND SUBSTRATE COMPRISING THE SAME

(71) Applicant: National Chiao Tung University, Hsinchu City (TW)

(72) Inventors: Chih CHEN, Hsinchu City (TW); King-Ning TU, Hsinchu City (TW); Chia-Ling LU, Tainan City (TW)

(21) Appl. No.: 14/471,638

(22) Filed: Aug. 28, 2014

(30) Foreign Application Priority Data
Aug. 30, 2013 (TW) 102131258

(51) Int. Cl. C30B 19/10; C30B 29/02; C30B 30/02; H05K 1/11; C30B 29/60; H01L 23/48; H05K 1/09; C22C 9/00; C30B 33/02

(52) U.S. Cl. CPC C30B 19/103; C22C 9/00; C30B 29/02; C30B 30/02; C30B 33/02; C30B 29/605; H01L 23/481; H05K 1/097; H05K 1/115; H05K 2201/09545
USPC 428/641; 420/469; 205/227; 205/50; 428/674

(57) ABSTRACT

The present invention relates to a single crystal copper having [100] orientation and a volume of 0.1˜4.0×10⁶ μm³. The present invention further provides a manufacturing method for the single crystal copper and a substrate comprising the same.

### CROSS REFERENCE TO RELATED APPLICATION

This application claims the benefits of the Taiwan Patent Application Serial Number 102131258, filed on Aug. 30, 2013, the subject matter of which is incorporated herein by reference.

### BACKGROUND OF THE INVENTION

1. Field of the Invention

The present invention relates to a single crystal copper. A novel method is employed to prepare a large single crystal copper having [100] orientation on a substrate. The single crystal copper is suitable for use as under bump metal (UBM), interconnect of a semiconductor chip, a metal wire or a circuit of a substrate.

2. Description of Related Art

Single crystal copper is formed of a crystal grain with a fixed crystal orientation, having good physical properties, and better elongation and a low resistivity compared with the polycrystalline copper. In addition, because the absence of transverse grain boundaries significantly improves the electromigration lifetime, and the diffusion rate of the (100) crystal plane is slower than that of other crystal planes, single crystal copper is suitable for use as a under bump metal pad and copper interconnect of the integrated circuit, and greatly contributes to the development of the integrated circuits in industrial applications.

Generally, the electromigration resistance of metal influences the reliability of an electronic device. The past studies have found three methods to improve the electromigration resistance of copper: the first method is to change the lattice structure of a wire, such that the internal grain structure has a preferred orientation; the second method is to increase the grain size, so as to reduce the number of the grain boundaries, thereby reducing the atomic migration path; and the third method is to add a nano-twinned crystal metal, so as to slow the loss rate of atoms due to electromigration to twin grain boundary.

Regarding the first and the second methods, the single crystal copper structure is formed by pulse electroplating in the prior art. However, there are two major deficiencies in the prior art. First, the single crystal copper grain is a bulk and cannot be directly grown on a silicon substrate for use in the microelectronics industry. Moreover, with reference to the recent related articles by Jun Liu et al., although the growth orientation of copper crystal can be controlled and a large grain can be obtained by optimizing the electroplating parameters of the pulse electroplating, the obtained crystal suffers from the problem of having contaminant of small grain copper, failing to fully grow as single crystal copper (referring to Jun Liu, Changqing Liu, Paul P Conway, “Growth mechanism of copper column by electrodeposition for electronic interconnections,” Electronics Systemintegration Technology Conference, p 679-84 (2008) and Jun Liu, Changqing Liu, Paul P Conway, Jun Zeng, Changhai Wang, “Growth and Recrystallization of Electroplated Copper Columns,” International

Conference on Electronic Packaging Technology & High Density Packaging, p 695-700 (2009)).

In view of the rapid development of electronic manufacture industry, what is needed in the art is to research and develop a single crystal copper of high conductivity, low resistivity, and extremely high elongation. The inventors have developed a better solution, which not only prepare a single crystal copper having a specific orientation by a simple process, but also can break through the conventional limit on grain size of the single crystal copper.

### SUMMARY OF THE INVENTION

An object of the present invention is to provide a single crystal copper and a substrate comprising the same by a method for manufacturing a single crystal copper, to obtained a single crystal copper having a [100] orientation.

To achieve the above object, the present invention provides a single crystal copper having a [100] orientation and a volume of 0.1−4.0×10⁶ μm³, preferably 20−1.0×10⁶ μm³, and more preferably 450−8.0×10⁵ μm³.

The grain shape of the single crystal copper is not particularly limited and may be cylindrical, linear, cubic, rectangular, irregular, and so on. When the single crystal copper has a cylindrical shape, the diameter thereof may be 1-500 μm, preferably 5-300 μm, and more preferably 10-100 μm, and when the single crystal copper has a linear shape, the linear length thereof may be up to 700 μm. In addition, regardless of the shape of the single crystal copper, its thickness may be 0.1-50 μm, preferably 1-15 μm, and more preferably 5-10 μm.

The above-mentioned single crystal copper may be used as a under bump metal (UBM) pad, interconnect of a semiconductor chip, a metal wire, or a circuit of a substrate, but is not particularly limited thereto.

The present invention further provides a method for manufacturing a single crystal copper, wherein a nano-twinned crystal copper pillar having a high density and regularly arranged grains is first formed on a substrate by the electroplating method, and then annealed to result in an abnormal grain growth by recrystallization, thereby generating a single crystal copper having a [100] orientation. The method for manufacturing a single crystal copper of the present invention comprises the following steps:

(A) providing an electroplating apparatus, comprising an anode, a cathode, an electroplating solution, and a power supply, wherein the power supply is connected to the anode and the cathode respectively, and the anode and the cathode are dipped in the electroplating solution which comprises: a copper salt, an acid and a chloride ion source;

(B) performing an electroplating by a power provided by the power supply to grow a nano-twinned crystal copper pillar on a surface of the cathode, wherein the nano-twinned crystal copper pillar comprises a plurality of nano-twinned crystal copper grains; and

(C) annealing the cathode with the nano-twinned crystal copper pillar at 350-600° C. for 0.5-3 hours to obtain a single crystal copper, wherein the single crystal copper has a [100] orientation and a volume of 0.1−4.0×10⁶ μm³.

In the step (A), the cathode may comprise a seed layer which is a copper layer having a thickness of 0.1-0.3 μm, and the seed layer may be formed by a physical vapor deposition (PVD), but is not particularly limited.

In the step (B), the nano-twinned crystal copper pillar grows on the seed layer.

In the step (B), a growth rate of the nano-twinned crystal copper pillar is 1-3 nm/cycle, and preferably 1.5-2.5 nm/cycle.

In the step (B), the nano-twinned crystal copper may have a thickness of 0.1-50 μm, preferably 1-15 μm, and more preferably 5-10 μm.

In the above-described step (B), the power supply may be a high speed pulse power supply for electroplating, and the electroplating is performed under an operation condition of 0.1/2-0.1/0.5 Tₒₙ/T_{off} (sec) with a current density of 0.01-0.2 A/cm². Basically, in addition to the high speed pulse power supply for electroplating, a direct current power supply may also be used as the power supply for electroplating, or both above may be used alternately.

In the electroplating solution of the step (A), a main function of the chloride ions is to fine tune the grain growth orientation, such that the twinned crystal metal has a preferred orientation. In addition, the acid may be either an organic or inorganic acid, to increase the electrolyte concentration, thereby increasing the electroplating rate. For example, sulfuric acid, methanesulfonic acid, or mixtures thereof may be used. Furthermore, the acid concentration in the electroplating solution may preferably be 80-120 g/L. Further, the electroplating solution should also contain a copper ion source (i.e., a copper salt, such as copper sulfate or copper methanesulfonate). The preferred composition of the electroplating solution may further include an additive selected from the group consisting of: gelatin, a surfactant, a lattice modifier, and mixtures thereof, to fine tune the grain growth orientation by adjusting the additive.

In the above-described step (A), the copper salt is preferably copper sulfate. The acid is preferably sulfuric acid, methanesulfonic acid or mixtures thereof, and the concentration of the acid is preferably 80-120 g/L. The substrate may be selected from the group consisting of a silicon substrate, a glass substrate, a quartz substrate, a metal substrate, a plastic substrate, a printed circuit board, a Group III-V substrate and mixtures thereof, and preferably a silicon substrate, but it is not particularly limited.

The present invention further provides a substrate with the above-described single crystal copper, which comprises a substrate; and the single crystal copper of the present invention. The single crystal copper is disposed on the substrate, and may be configured as a circuit, or an array, depending on the different applications or requirements. The single crystal copper and the substrate have the same features as described above, and will not be repeated herein for simplicity.

The single crystal copper prepared by the method of the present invention has a [100] orientation and a large grain, and its excellent characteristics such as mechanical, electrical and light properties and heat stability and electromigration resistance can significantly improve the industrial applicability.

### BRIEF DESCRIPTION OF THE DRAWINGS

The above and other objects, features and other advantages of the present invention will be more clearly understood from the following detailed description taken in conjunction with the accompanying drawings.

FIG. 1 shows a schematic diagram of the electroplating apparatus according to the Example of the present invention.

FIG. 2A shows the focused ion beam (FIB) graph of a top view of one single crystal copper grain having a diameter of 17 μm.

FIG. 2B shows the analysis graph of the EBSD orientation map of one single crystal copper grain having a diameter of 17 μm.

FIG. 3A shows the focused ion beam (FIB) graph of a top view of the single crystal copper array having a diameter of 25 μm.

FIG. 3B shows the focused ion beam (FIB) graph of a top view of one single crystal copper grain having a diameter of 25 μm.

FIG. 3C shows the focused ion beam (FIB) graph of a cross-sectional view of FIG. 3B.

FIG. 3D shows the analysis graph of the EBSD orientation map of FIG. 3A.

FIG. 3E shows the analysis graph of the EBSD orientation map of FIG. 3B.

FIG. 4 shows the analysis graph of the EBSD orientation map of one single crystal copper grain having a diameter of 50 μm.

FIG. 5A shows the focused ion beam (FIB) graph of a top view of the single crystal copper array having a diameter of 100 μm.

FIG. 5B shows the analysis graph of the EBSD orientation map of FIG. 5A.

### DETAILED DESCRIPTION OF THE PREFERRED EMBODIMENT

Hereinafter, the actions and the effects of the present invention will be explained in more detail via specific examples of the invention. However, these examples are merely illustrative of the present invention and the scope of the invention should not be construed to be defined thereby.

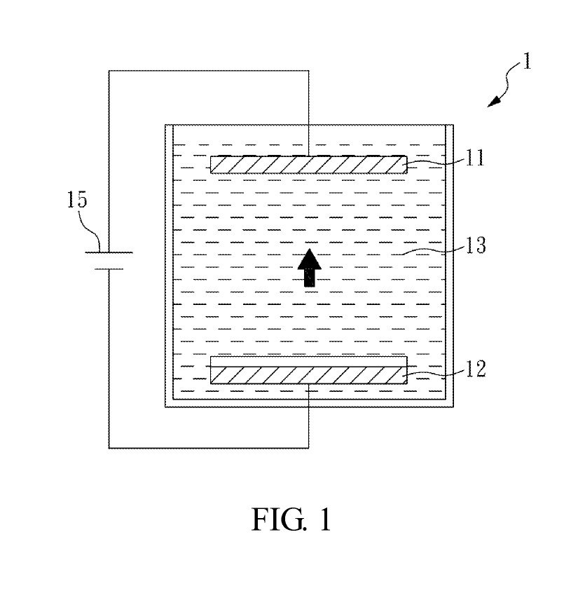

The electroplating apparatus shown in FIG. 1 is provided, which comprises: an anode 11, a cathode 12, an electroplating solution 13, and a power supply 15, wherein the power supply 15 is connected to the anode 11 and the cathode 12 respectively, and the anode 11 and the cathode 12 are dipped in the electroplating solution 13.

In this case, the anode 11 is made of a commercial 99.99% pure copper target, the cathode 12 is a silicon chip, and the electroplating solution 13 comprises copper sulfate (Cu ion concentration of 20-60 g/L), chloride ions (10-100 ppm), and methanesulfonic acid (80-120 g/L), and may be optionally added with other surfactants or lattice modifiers (such as 1-100 ml/L of BASF Lugalvan). In addition, the electroplating solution 13 may further include an organic acid (e.g. methanesulfonic acid), gelatin, and so on.

On the silicon chip cathode 12, a copper film having a thickness of 0.2 μm may be formed by physical vapor deposition (PVD) to serve as a seed layer, such that the current source for electroplating only needs to touch the vicinity of the edge of the silicon chip to conduct the current uniformly to the center of the chip, thereby achieving thickness uniformity of the seed layer.

In this Example, the power supply 14 is a high speed pulse power supply for electroplating, and the electroplating is performed under an operation condition of 0.1/2-0.1/0.5 Tₒₙ/T_{off} (sec), such as 0.1/2, 0.1/1 or 0.1/0.5, with a current density of 0.01-0.2 A/cm², and most preferably 0.05 A/cm². Under this condition, the nano-twinned crystal copper grows at a growth rate of 2 nm/cycle to a thickness of 6-10 82 m. Then, the nano-twinned crystal copper is patterned to form a nano-twinned crystal copper pillar on the silicon chip. Basically, the pattern of the nano-twinned crystal copper pillar is not particularly limited and may be cylindrical, linear, cubic, rectangular, irregular, and so on, and may be arranged in an array form.

Next, the silicon chip with the nano-twinned crystal copper pillar thereon is placed in furnace tube to perform an annealing process under a high vacuum (8×10⁻⁷ torr) at a temperature of 400-450° C. for 0.5-1 hour, so as to form the single crystal copper having a [100] orientation with a large particle size.

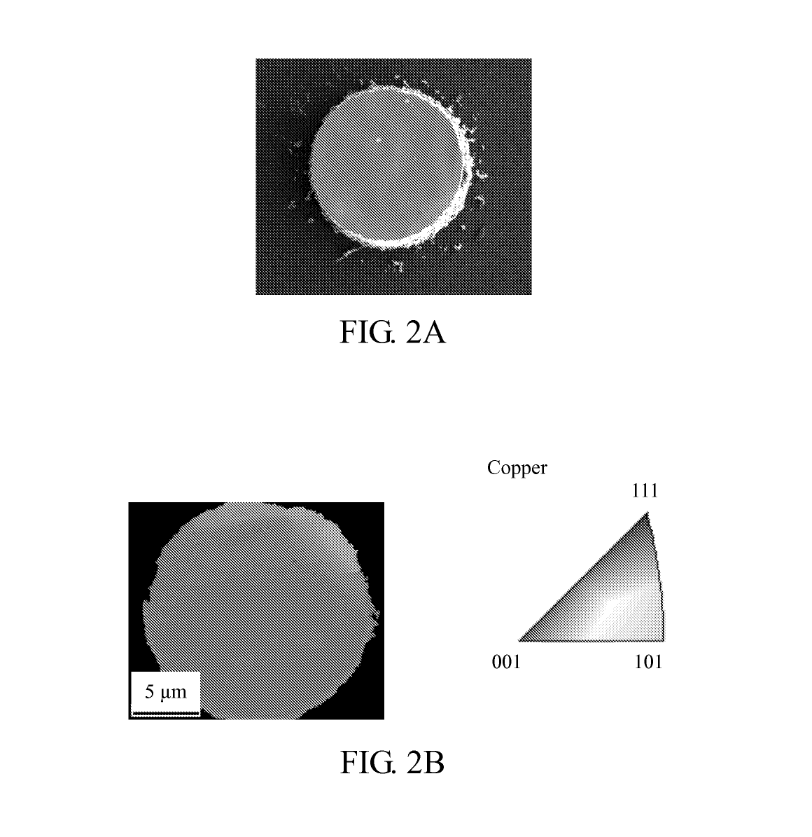

FIG. 2A shows the focused ion beam (FIB) graph of a top view of one single crystal copper grain having a diameter of 17 μm, and FIG. 2B shows the analysis graph of the EBSD orientation map of one single crystal copper grain having a diameter of 17 μm. The annealed condition for FIGS. 2A, 2B is 450° C., 60 minutes. According to FIGS. 2A-2B, it can be confirmed that the single crystal copper of this Example has a [100] orientation, and one single crystal copper grain has a volume of 1362 μm³.

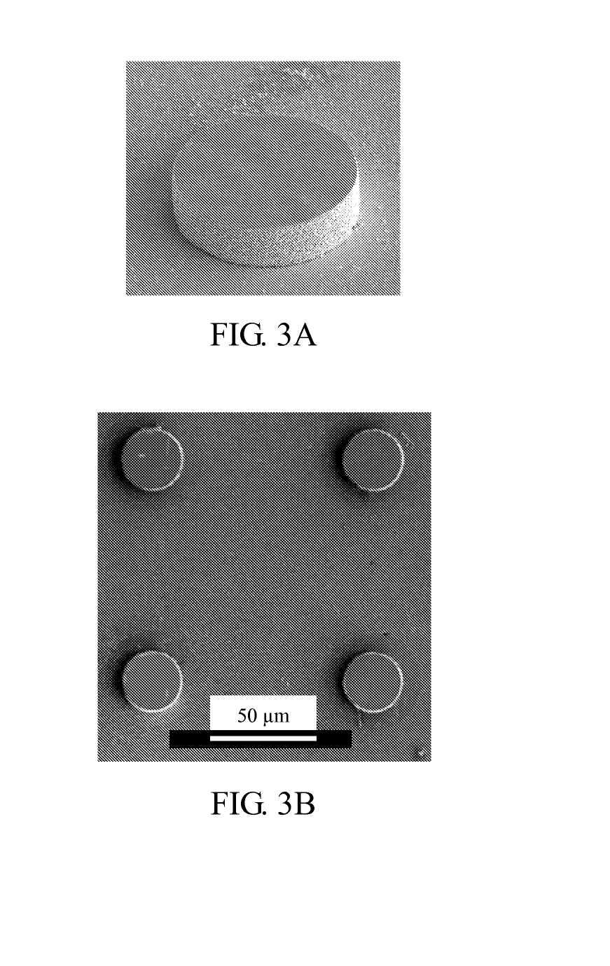

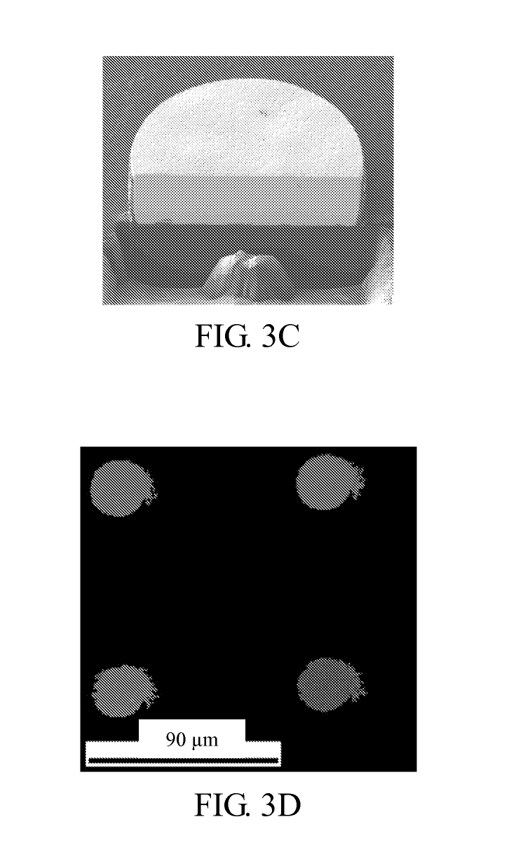

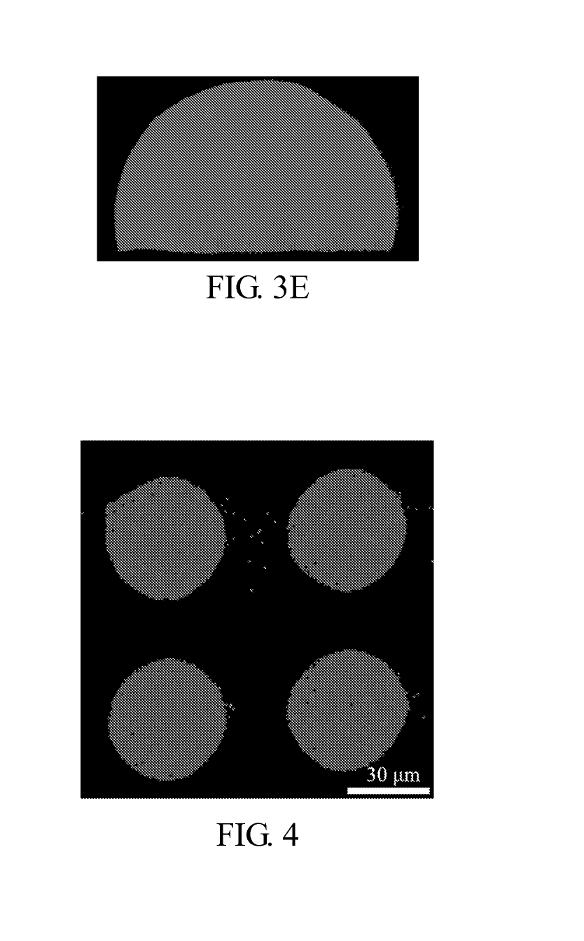

FIG. 3A shows the focused ion beam (FIB) graph of a top view of the single crystal copper array having a diameter of 25 μm. FIG. 3B shows the focused ion beam (FIB) graph of a top view of one single crystal copper grain array having a diameter of 25 μm. FIG. 3C shows the focused ion beam (FIB) graph of a cross-sectional view of FIG. 3B. FIG. 3D shows the analysis graph of the EBSD orientation map of FIG. 3A. FIG. 3E shows the analysis graph of the EBSD orientation map of FIG. 3B. The annealing condition to obtain the single crystal copper array of this Example shown in FIGS. 3A-3E is 450° C., 60 minutes. The results show that the single crystal copper having a diameter of 25 μm has a [100] orientation without contaminant of other crystal grains, and one single crystal copper grain has a volume of 2945 μm³.

FIG. 4 shows the analysis graph of the EBSD orientation map of one single crystal copper grain having a diameter of 50 μm. The annealing condition to obtain the single crystal copper array of this Example shown in FIG. 4 is 450° C., 60 minutes. The results confirms that the single crystal copper having a diameter of 50 μm has a [100] orientation, and one single crystal copper grain has a volume of 1.2×10⁴ μm³.

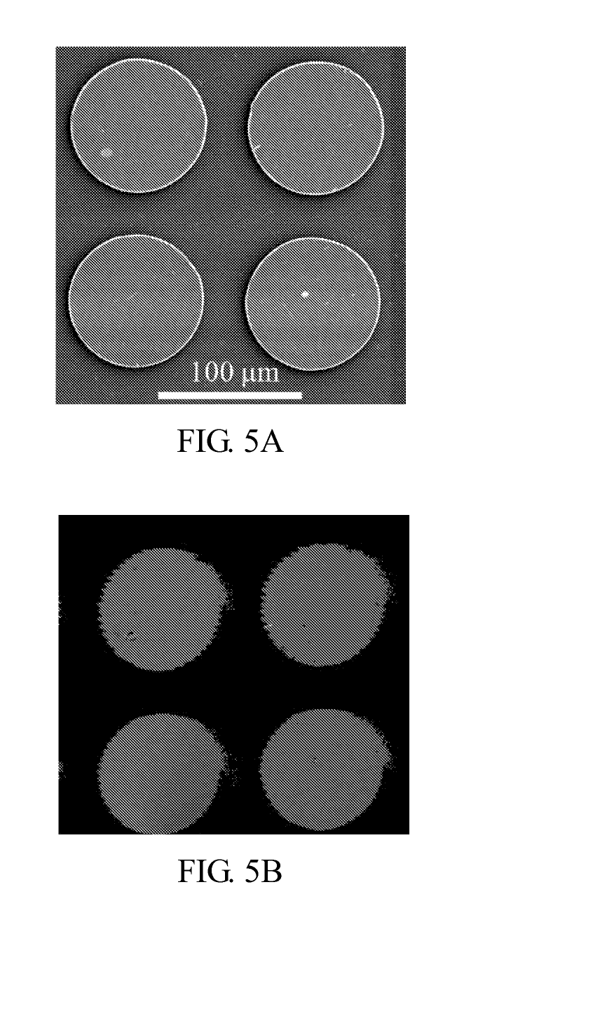

FIG. 5A shows the focused ion beam (FIB) graph of a top view of the single crystal copper array having a diameter of 100 μm. FIG. 5B shows the analysis graph of the EBSD orientation map of FIG. 5A. The results of FIGS. 5A-5B indicate that the single crystal copper prepared by the present invention having a diameter of 100 μm has a [100] orientation, and one single crystal copper grain has a volume of 4.8×10⁴ μm³.

Since the single crystal copper has good physical properties, as well as better elongation and a low resistivity compared with the conventional polycrystalline copper, and the absence of the transverse grain boundaries, thus the electromigration lifetime can be significantly improved. Therefore, the single crystal copper of the present invention is suitable for use as a under bump metal pad and a copper interconnect of the integrated circuit, and greatly contributes to the development of the integrated circuits in industrial applications.

It should be understood that these examples are merely illustrative of the present invention and the scope of the invention should not be construed to be defined thereby, and the scope of the present invention will be limited only by the appended claims.

What is claimed is:

1. A single crystal copper, having a [100] orientation and a volume of 0.1−4.0×10⁶ μm³.

2. The single crystal copper of claim 1, having a volume of 20−1.0×10⁶ μm³.

3. The single crystal copper of claim 1, having a thickness of 0.1-50 μm.

4. The single crystal copper of claim 1, which is used as a under bump metal pad, interconnect of a semiconductor chip, a metal wire, or a circuit of a substrate.

5. A method for manufacturing a single crystal copper, comprising the following sequential steps:
(A) providing an electroplating apparatus, comprising an anode, a cathode, an electroplating solution, and a power supply, wherein the power supply is connected to the anode and the cathode respectively, and the anode and the cathode are dipped in the electroplating solution which comprises: a copper salt, an acid and a chloride ion source;
(B) performing an electroplating by a power provided by power supply to grow a nano-twinned crystal copper pillar on a surface of the cathode, wherein the nano-twinned crystal copper pillar comprises a plurality of nano-twinned crystal copper grains; and
(C) annealing the cathode with the nano-twinned crystal copper pillar at 350-600° C. for 0.5-3 hours to obtain a single crystal copper,
wherein the single crystal copper has a [100] orientation and a volume of 0.1−4.0×10⁶ μm³.

6. The method of claim 5, wherein, in the step (A), the cathode comprises a seed layer which is a copper layer having a thickness of 0.1-0.3 μm and formed by a physical vapor deposition (PVD).

7. The method of claim 6, wherein, in the step (B), the nano-twinned crystal copper pillar grows on the seed layer.

8. The method of claim 5, wherein, in the step (B), a growth rate of the nano-twinned crystal copper pillar is 1-3 nm/cycle.

9. The method of claim 5, wherein, in the step (B), the nano-twinned crystal copper pillar has a thickness of 5-15 μm.

10. The method of claim 5, wherein, in the step (B), the power supply is a high speed pulse power supply for electroplating, and the electroplating is performed under an operation condition of 0.1/2-0.1/0.5 Tₒₙ/T_{off} (sec) with a current density of 0.01-0.2 A/cm².

11. The method of claim 5, wherein the single crystal copper has a volume of 20−1.0×10⁶ μm³.

12. The method of claim 5, wherein the single crystal copper has a thickness of 0.1-50 μm.

13. The method of claim 5, wherein, in the step (A), the electroplating solution further comprises a gelatin, a surfactant, a lattice modifier or mixtures thereof.

14. The method of claim 5, wherein, in the step (A), the copper salt is copper sulfate.

15. The method of claim 5, wherein, in the step (A), the acid is sulfuric acid, methanesulfonic acid, or mixtures thereof.

16. The method of claim 5, wherein, in the step (A), the acid has a concentration of 80-120 g/L.

17. The method of claim 5, wherein, in the step (A), the substrate is selected from the group consisting of: a silicon substrate, a glass substrate, a quartz substrate, a metal substrate, a plastic substrate, a printed circuit board, a Group III-V substrate and mixtures thereof.

18. A substrate with a single crystal copper, comprising:
a substrate; and
a single crystal copper disposed on the substrate and having a [100] orientation and a volume of 0.1−4.0×10⁶ μm³.

19. The substrate with a single crystal copper of claim 18, wherein, the substrate is selected from the group consisting of: a silicon substrate, a glass substrate, a quartz substrate, a metal substrate, a plastic substrate, a printed circuit board, a Group III-V substrate and mixtures thereof.
